(19) United States
(12) Patent Application Publication
(10) Pub. No.: US 2024/0089619 A1
(43) Pub. Date: Mar. 14, 2024

(54) LIGHT DETECTION DEVICE AND ELECTRONIC APPARATUS

(71) Applicant: SONY SEMICONDUCTOR SOLUTIONS CORPORATION, KANAGAWA (JP)

(72) Inventors: KAZUYOSHI YAMASHITA, KANAGAWA (JP); KAZUHIRO GOI, KANAGAWA (JP); SHINICHIRO NOUDO, KANAGAWA (JP); TOMOHIRO YAMAZAKI, KANAGAWA (JP); ATSUSHI TODA, KANAGAWA (JP); TAKAYUKI OGASAHARA, KANAGAWA (JP); KOJI MIYATA, KANAGAWA (JP)

(21) Appl. No.: 18/259,783

(22) PCT Filed: Dec. 24, 2021
(86) PCT No.: PCT/JP2021/048118

§ 371 Date: Jun. 29, 2023

(30) Foreign Application Priority Data
Jan. 7, 2021 (JP) 2021-001227

(51) Int. Cl. H04N 25/13

(52) U.S. Cl. CPC H04N 25/134; H04N 25/772

(57) ABSTRACT

The present technology relates to a light detection device and an electronic apparatus capable of increasing sensitivity of a specific pixel. The light detection device includes a pixel array unit in which a plurality of pixels is regularly arranged, the plurality of pixels including a first pixel and a second pixel, the first pixel including at least a photodiode and one or more pixel transistors, the second pixel including at least a photodiode larger in size than the photodiode of the first pixel, in which the pixel transistor in the first pixel is shared by the first pixel and the second pixel. The present technology may be applied to image sensors and the like, for example.

### TECHNICAL FIELD

The present technology relates to a light detection device and an electronic apparatus, and particularly relates to a light detection device and an electronic apparatus capable of increasing sensitivity of a specific pixel.

### BACKGROUND ART

Various structures for increasing sensitivity of a CMOS image sensor have been proposed. For example, Patent Document 1 discloses a technique for increasing sensitivity of a specific pixel by making any one of a red (R) pixel, a green (G) pixel, or a blue (B) pixel larger in photodiode size than the other pixels.

### CITATION LIST

### Patent Document

Patent Document 1: US Patent Application Publication No. 2012/0013777 Specification

### SUMMARY OF THE INVENTION

### Problems to be Solved by the Invention

Patent Document 1, however, does not disclose a layout of pixel transistors and the like necessary for actual fabrication of an image sensor. In actual fabrication, if elements such as pixel transistors are arranged in a manner similar to a case where all pixels have the same photodiode size, some pixels may suffer a reduction in saturation signal amount or sensitivity, so that it is necessary to find any ingenious way.

The present technology has been made in view of such circumstances, and it is therefore an object of the present technology to increase sensitivity of a specific pixel.

### Solutions to Problems

A light detection device according to a first aspect of the present technology includes a pixel array unit in which a plurality of pixels is regularly arranged, the plurality of pixels including a first pixel and a second pixel, the first pixel including at least a photodiode and one or more pixel transistors, the second pixel including at least a photodiode larger in size than the photodiode of the first pixel, in which the pixel transistor in the first pixel is shared by the first pixel and the second pixel.

An electronic apparatus according to a second aspect of the present technology includes a light detection device including a pixel array unit in which a plurality of pixels is regularly arranged, the plurality of pixels including a first pixel and a second pixel, the first pixel including at least a photodiode and one or more pixel transistors, the second pixel including at least a photodiode larger in size than the photodiode of the first pixel, in which the pixel transistor in the first pixel is shared by the first pixel and the second pixel.

According to the first and second aspects of the present technology, the pixel array unit in which a plurality of pixels is regularly arranged is provided, the plurality of pixels including the first pixel and the second pixel, the first pixel including at least a photodiode and one or more pixel transistors, the second pixel including at least a photodiode larger in size than the photodiode of the first pixel, and the pixel transistor in the first pixel is shared by the first pixel and the second pixel.

The light detection device and the electronic apparatus may be independent devices or may be modules incorporated in another device.

### BRIEF DESCRIPTION OF DRAWINGS

FIG. 1 is a diagram illustrating a schematic configuration of a solid-state imaging device to which the present technology is applied.

FIG. 2 is a diagram illustrating a circuit configuration example of a pixel unit shared by two pixels.

FIG. 3 is a plan view of a first circuit layout example of the pixel unit shared by two pixels.

FIG. 4 is a plan view of a second circuit layout example of the pixel unit shared by two pixels.

FIG. 5 is a plan view of a modification of the second circuit layout example.

FIG. 6 is a diagram illustrating a circuit configuration example of a pixel unit shared by four pixels.

FIG. 7 is a plan view of a first circuit layout example of the pixel unit shared by four pixels.

FIG. 8 is a plan view of a second circuit layout example of the pixel unit shared by four pixels.

FIG. 9 is a plan view of a configuration example of a color filter layer.

FIG. 10 is a diagram illustrating a varied size layout example of the color filter layer and an on-chip lens.

FIG. 11 is a plan view of a configuration example of the color filter layer in a case where a plane shape is a rectangle.

FIG. 12 is a plan view of a layout example of RGBW filters.

FIG. 13 is a plan view of an example where the color filter layer and the on-chip lens illustrated in FIG. 10 are arranged in units of four pixels of two rows and two columns.

FIG. 14 is a block diagram illustrating a configuration example of an imaging device as an electronic apparatus to which the present technology is applied.

FIG. 15 is a diagram for describing a usage example of an image sensor.

### MODE FOR CARRYING OUT THE INVENTION

Hereinafter, a mode for carrying out the present technology (hereinafter, referred to as an embodiment) will be described. Note that the description will be given in the following order.
1. Schematic Configuration Example of Solid-State Imaging Device
2. Circuit Configuration Example of Pixel Unit Shared by Two Pixels
3. First Circuit Layout Example of Pixel Unit Shared by Two Pixels
4. Second Circuit Layout Example of Pixel Unit Shared by Two Pixels
5. Circuit Configuration Example of Pixel Unit Shared by Four Pixels
6. First Circuit Layout Example of Pixel Unit Shared by Four Pixels
7. Second Circuit Layout Example of Pixel Unit Shared by Four Pixels
8. Layout Example of Color Filter Layer
9. Varied Size Layout Example of Color Filter Layer and On-Chip Lens
10. Combination of PDs Having Different Sizes
11. Application Example to Electronic Apparatus

Note that in the drawings referred to in the following description, the same or similar portions are denoted by the same or similar reference numerals. However, the drawings are schematic, and the relationship between the thickness and the plane dimension, the ratio of the thickness of each layer, and the like are different from the actual ones. Furthermore, the drawings may include portions having different dimensional relationships and ratios.

Furthermore, definitions of directions such as up and down in the following description are merely definitions for convenience of description, and do not limit the technical idea of the present disclosure. For example, when an object is observed by rotating the object by 90°, the upper and lower sides are read by converting into left and right, and when an object is observed by rotating the object by 180°, the upper and lower sides are read by inverting.

<1. Schematic Configuration Example of Solid-State Imaging Device>

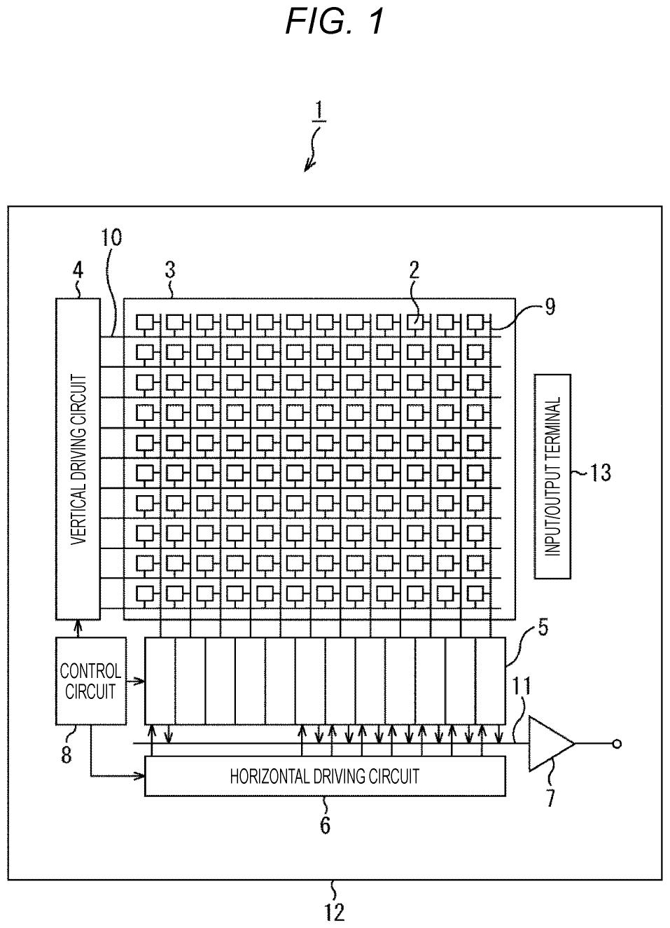

FIG. 1 illustrates a schematic configuration of a solid-state imaging device to which the present technology is applied.

A solid-state imaging device 1 in FIG. 1 is configured such that a semiconductor substrate 12 using silicon (Si), for example, as a semiconductor includes a pixel array unit 3 in which pixels 2 are arranged in a two-dimensional array pattern and a peripheral circuit unit around the same. The peripheral circuit unit includes a vertical driving circuit 4, a column signal processing circuit 5, a horizontal driving circuit 6, an output circuit 7, a control circuit 8, and the like.

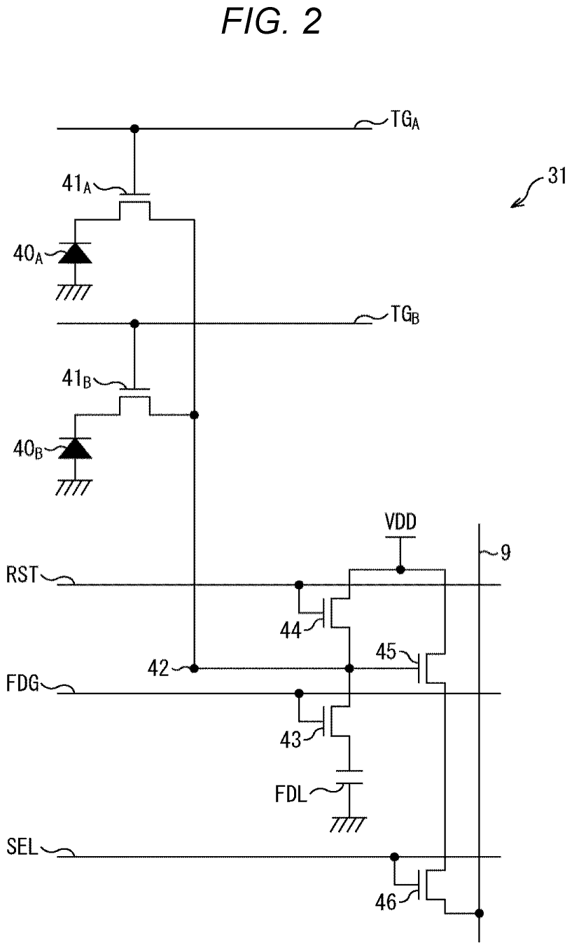

Each of the pixels 2 arranged in the pixel array unit 3 has a shared pixel structure in which a photodiode (hereinafter, denoted as PD) is provided as a photoelectric conversion element, and a readout circuit that reads out a signal charge generated by the PD is shared by a plurality of pixels. Although details of each of the pixels 2 will be described later with reference to FIG. 2 and the subsequent drawings, the circuit shared by the plurality of pixels includes, for example, a floating diffusion (FD), an amplification transistor, a reset transistor, and a selection transistor.

The control circuit 8 receives an input clock and data giving a command of an operation mode and the like and outputs data of internal information and the like of the solid-state imaging device 1. That is, the control circuit 8 generates a clock signal and a control signal which serve as a reference for operation of the vertical driving circuit 4, the column signal processing circuit 5, the horizontal driving circuit 6, and the like on the basis of a vertical synchronization signal, a horizontal synchronization signal, and a master clock. Then, the control circuit 8 outputs the generated clock signal and control signal to the vertical driving circuit 4, the column signal processing circuit 5, the horizontal driving circuit 6, and the like.

The vertical driving circuit 4 including a shift register, for example, selects a predetermined pixel driving wiring 10 and supplies a pulse for driving the pixel 2 to the selected pixel driving wiring 10 to drive the pixels 2 row by row. That is, the vertical driving circuit 4 sequentially selects and scans each of the pixels 2 of the pixel array unit 3 row by row in a vertical direction and supplies a pixel signal based on a signal charge generated according to a light receiving amount by a photoelectric converting unit of each of the pixels 2 to the column signal processing circuit 5 through a vertical signal line 9.

The column signal processing circuit 5 arranged for each column of the pixels 2 performs signal processing such as noise removal on the signals output from the pixels 2 of one column for each pixel column. For example, the column signal processing circuit 5 performs the signal processing such as correlated double sampling (CDS) for removing a fixed pattern noise specific to the pixel and AD conversion.

The horizontal driving circuit 6 including a shift register, for example, sequentially selects each of the column signal processing circuits 5 by sequentially outputting horizontal scanning pulses and outputs the pixel signal from each of the column signal processing circuits 5 to a horizontal signal line 11.

The output circuit 7 performs signal processing on the signals sequentially supplied from each of the column signal processing circuits 5 through the horizontal signal line 11 and outputs the processed signals. In the output circuit 7, for example, there is a case where only buffering is performed, or a case where black level adjustment, column variation correction, various types of digital signal processing, and the like are performed. An input/output terminal 13 communicates signals with the outside.

The solid-state imaging device 1 formed in the above-described manner is a CMOS image sensor referred to as a column AD type in which the column signal processing circuit 5 which performs CDS processing and AD conversion processing is arranged for each pixel column.

The solid-state imaging device 1 can be a back-illuminated MOS solid-state imaging device in which light is incident from the back surface side opposite to the front surface side of the semiconductor substrate 12 in which the pixel transistors are formed, but may be a front-illuminated MOS solid-state imaging device.

<2. Circuit Configuration Example of Pixel Unit Shared by Two Pixels>

Each of the pixels 2 regularly arranged in the pixel array unit 3 has a shared pixel structure in which at least a part of the readout circuit that reads out a signal charge generated by the PD is shared by a plurality of pixels.

First, a case where at least a part of the readout circuit is shared by two pixels will be described.

FIG. 2 illustrates a circuit configuration example of a pixel unit that is a unit to be shared in a case where the readout circuit is shared by two pixels.

A pixel unit 31 in FIG. 2 includes PDs 40_{A} and 40_{B}, transfer transistors 41_{A} and 41_{B}, an FD 42, a switching transistor 43, a reset transistor 44, an amplification transistor 45, a selection transistor 46, and an additional capacity FDL. Each pixel transistor, that is, the transfer transistors 41_{A} and 41_{B}, the switching transistor 43, the reset transistor 44, the amplification transistor 45, and the selection transistor 46, includes an N-type MOS transistor.

In the pixel unit 31 having the two pixels in FIG. 2 as a unit of sharing, each pixel includes only the PD 40 and the transfer transistor 41, and the FD 42, the switching transistor 43, the reset transistor 44, the amplification transistor 45, the selection transistor 46, and the additional capacity FDL are shared by the two pixels. When the two pixels constituting the pixel unit 31 are separated into a pixel 2A and a pixel 2B, the pixel 2_{A} includes the PD 40_{A} and the transfer transistor 41_{A}, and the pixel 2_{B} includes the PD 40_{B} and the transfer transistor 41_{B}. The FD 42, the switching transistor 43, the reset transistor 44, the amplification transistor 45, the selection transistor 46, and the additional capacity FDL that are shared constitute the readout circuit.

The PD 40 generates and accumulates an electric charge (signal charge) corresponding to an amount of received light. The PD 40 has an anode terminal grounded and a cathode terminal connected to the FD 42 via the transfer transistor 41.

When turned on by a transfer signal TG, the transfer transistor 41 reads the electric charge generated by the PD 40 and transfers the electric charge to the FD 42. When turned on by a transfer signal TG_{A} for controlling the transfer transistor 41_{A}, the PD 40_{A} of the pixel 2_{A} reads an electric charge generated by the PD 40_{A} and transfers the electric charge to the FD 42. When turned on by a transfer signal TG_{B} for controlling the transfer transistor 41_{B}, the PD 40_{B} of the pixel 2_{B} reads an electric charge generated by the PD 40_{B} and transfers the electric charge to the FD 42.

The FD 42 retains the electric charge read from at least one of the PD 40_{A} or 40_{B}.

The switching transistor 43 switches a connection between the FD 42 and the additional capacity FDL in accordance with a capacity switching signal FDG to change conversion efficiency. Specifically, for example, when the amount of incident light is large, that is, luminous intensity is high, the vertical driving circuit 4 turns on the switching transistor 43 to connect the FD 42 and the additional capacity FDL. It is therefore possible to accumulate more electric charges when luminous intensity is high. On the other hand, when the amount of incident light is small, that is, luminous intensity is low, the vertical driving circuit 4 turns off the switching transistor 43 to disconnect the additional capacity FDL from the FD 42. It is therefore possible to increase conversion efficiency. Note that the switching transistor 43 and the additional capacity FDL may be omitted.

When the reset transistor 44 is turned on by a reset signal RST, the electric charge accumulated in the FD 42 is discharged to a drain (constant voltage source VDD) to reset an electric potential of the FD 42. Note that when the switching transistor 43 is also turned on simultaneously with the reset transistor 44, the additional capacity FDL can also be reset.

The amplification transistor 45 outputs a pixel signal corresponding to the electric potential of the FD 42. That is, the amplification transistor 45 constitutes a source follower circuit with a load MOS (not illustrated) as a constant current source connected via the vertical signal line 9, and the pixel signal indicating a level according to the electric charge accumulated in the FD 42 is output to the column signal processing circuit 5 (FIG. 1) from the amplification transistor 45 via the selection transistor 46.

The selection transistor 46 is turned on when the pixel unit 31 is selected by a selection signal SEL, and outputs the pixel signal generated by the pixel unit 31 to the column signal processing circuit 5 via the vertical signal line 9. Each signal line through which the transfer signal TG, the selection signal SEL, and the reset signal RST are transmitted corresponds to the pixel driving wiring 10 in FIG. 1.

In the pixel unit 31, in a case where the vertical driving circuit 4 turns on the transfer transistors 41_{A} and 41_{B} of the pixel 2_{A} and the pixel 2_{B} at different times in a time-division manner to sequentially transfer the respective electric charges accumulated in the PD 40_{A} and the PD 40_{B} to the FD 42, the pixel signal is output, in units of pixels, to the column signal processing circuit 5.

On the other hand, in a case where the vertical driving circuit 4 simultaneously turns on the transfer transistors 41_{A} and 41_{B} of the pixel 2_{A} and the pixel 2_{B} to simultaneously transfer the respective electric charges accumulated in the PD 40_{A} and the PD 40_{B} to the FD 42, the FD 42 functions as an addition unit, and an addition signal obtained by adding the pixel signals of the two pixels in the pixel unit 31 is output to the column signal processing circuit 5.

Therefore, the plurality of pixels 2 in the pixel unit 31 can output the pixel signal in units of one pixel or simultaneously output the pixel signals of the plurality of pixels 2 in the pixel unit 31 in accordance with a driving signal from the vertical driving circuit 4.

<3. First Circuit Layout Example of Pixel Unit Shared by Two Pixels>

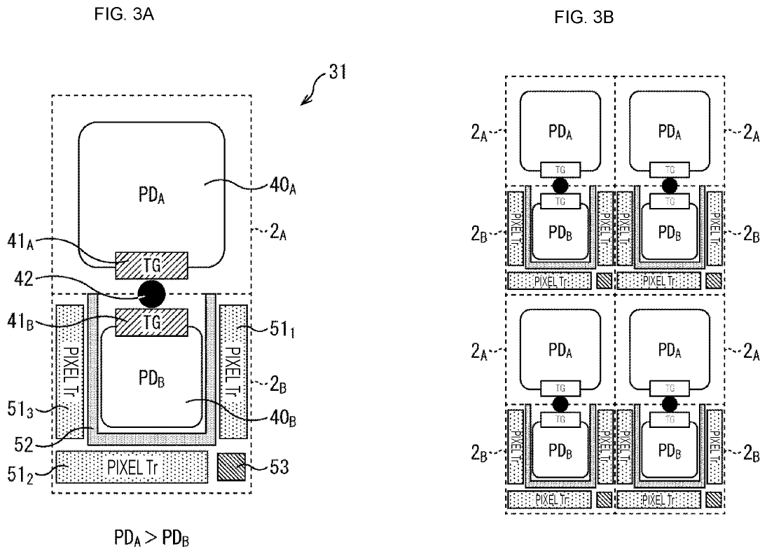

FIG. 3 is a plan view of a first circuit layout example of the pixel unit 31 shared by two pixels.

A of FIG. 3 is a plan view of one pixel unit 31 in the first circuit layout example.

The pixel unit 31 includes the pixel 2_{A} and the pixel 2_{B} arranged in a row in a vertical direction. Here, the vertical direction is a direction parallel to the vertical signal line 9 in the pixel array unit 3, and a horizontal direction is a direction parallel to the pixel driving wiring 10.

The PD 40_{A} and the transfer transistor 41_{A} are formed in a pixel region of the pixel 2_{A}, and the PD 40_{B} and the transfer transistor 41_{B} are formed in a pixel region of the pixel 2_{B}. The respective pixel regions of the pixel 2_{A} and the pixel 2_{B} each indicated by a rectangular dashed line have the same size. Furthermore, the FD 42 is formed at a boundary of the pixel regions of the pixel 2_{A} and the pixel 2_{B} and between the transfer transistor 41_{A} and the transfer transistor 41_{B}.

The PD 40_{A} of the pixel 2_{A} is formed larger in photodiode size than the PD 40_{B} of the pixel 2_{B}. Pixel transistor regions 51₁ to 51₃ are formed in the pixel region of the pixel 2_{B} formed smaller in photodiode size than the pixel 2_{A}. The switching transistor 43, the reset transistor 44, the amplification transistor 45, the selection transistor 46, and the additional capacity FDL described above are dispersedly arranged in the pixel transistor regions 51₁ to 51₃.

An element isolation part 52 is formed between the pixel transistor regions 51₁ to 51₃ and the PD 40_{B}. The element isolation part 52 may include, for example, shallow trench isolation (STI) or a P-type impurity region. Arranging, in a concentrated manner, the pixel transistor regions 51₁ to 51₃ in one pixel region of the pixel 2_{B} also allows a reduction in area of the element isolation part 52, and it is therefore possible to prevent the occurrence of dark current due to a crystal defect caused by the formation of the element isolation part 52.

Furthermore, a well contact part 53 where a predetermined voltage (for example, GND) is applied to the semiconductor substrate (P well) 12 in which each pixel transistor is formed is disposed at a predetermined portion of the pixel region of the pixel 2_{B}. In A of FIG. 3, it is disposed at a position that is one of four corners of the rectangular pixel region of the pixel 2_{B} and has an inside pixel region surrounded by the pixel transistor regions 51₁ and 51₂. The well contact part 53 includes a P-type impurity region that is heavily doped so as to make resistance lower, but there is a concern about generation of dark current due to a crystal defect. As described above, a region around the well contact part 53 is used as the pixel transistor region 51, and the well contact part 53 and the PD 40_{B} are arranged so as not to be adjacent to each other, thereby allowing a reduction in influence of the dark current on the PD 40_{B}. Note that the well contact part 53 may be disposed, for example, at a boundary of the pixel regions of the pixel 2_{A} and the pixel 2_{B}, or may be disposed in the pixel region of the pixel 2_{A}.

B of FIG. 3 is a plan view of an inside of a pixel array unit 3 in which a plurality of the pixel units 31 illustrated in A of FIG. 3 is regularly arranged. Note that, in B of FIG. 3, reference numerals other than the pixel 2_{A} and the pixel 2_{B} are omitted.

According to the first circuit layout example of the pixel unit 31 in FIG. 3, the pixel 2_{A} including the PD 40_{A} that is larger in photodiode size and the pixel 2_{B} including the PD 40_{B} that is smaller in photodiode size than the PD 40_{A} are arranged adjacent to each other in the vertical direction. All the pixel transistors shared by the pixel 2_{A} and the pixel 2_{B} are dispersedly arranged in the pixel transistor regions 51₁ to 51₃ of the pixel 2_{B} including the PD 40_{B} that is smaller in photodiode size. It is therefore possible to increase the photodiode size of the PD 40_{A} of the pixel 2_{A} as much as possible and thus increase the sensitivity of the PD 40_{A}. In other words, it is possible to increase an SN ratio of the pixel signal of the pixel 2_{A}. Furthermore, an increase in the saturation signal amount of the PD 40_{A} allows an increase in dynamic range.

Note that, in the first circuit layout example illustrated in FIG. 3, the pixel 2_{A} and the pixel 2_{B} constituting the pixel unit 31 are arranged adjacent to each other in the vertical direction, but may be arranged adjacent to each other in the horizontal direction.

<4. Second Circuit Layout Example of Pixel Unit Shared by Two Pixels>

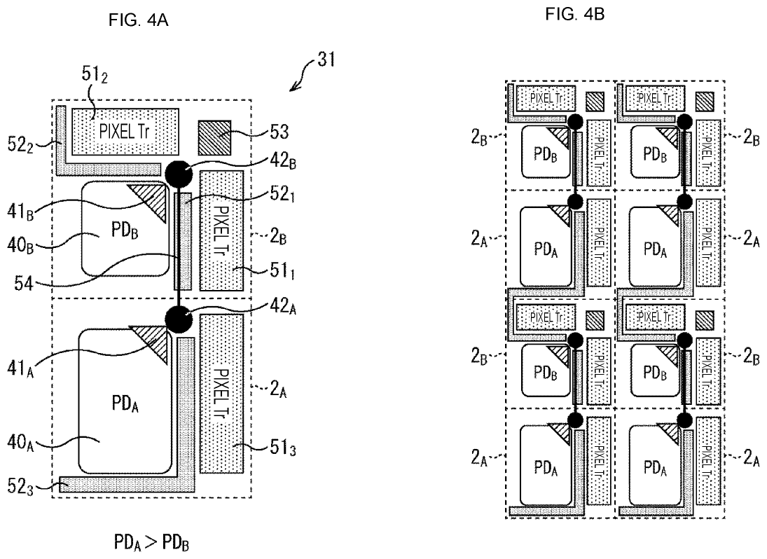

FIG. 4 is a plan view of a second circuit layout example of the pixel unit 31 shared by two pixels.

In FIG. 4, portions corresponding to the portions in FIG. 3 illustrated as the first circuit layout example are denoted by the same reference numerals, and description of the portions will be omitted as appropriate.

A of FIG. 4 is a plan view of one pixel unit 31 in the second circuit layout example.

In the first circuit layout example illustrated in FIG. 3, one FD 42 is formed at the boundary of the pixel regions of the pixel 2_{A} and the pixel 2_{B}, and the transfer transistor 41_{A} and the transfer transistor 41_{B} are formed such that the one FD 42 is interposed between the transfer transistor 41_{A} and the transfer transistor 41_{B}.

On the other hand, in the second circuit layout example in A of FIG. 4, the FD 42 is provided in both the pixel regions of the pixel 2_{A} and the pixel 2_{B}. The FD 42 provided in the pixel 2_{A} is denoted as an FD 42_{A}, and the FD 42 provided in the pixel 2_{B} is denoted as an FD 42_{B}. The FD 42_{A} and the FD 42_{B} are electrically connected by a metal wiring 54 in a wiring layer located above the semiconductor substrate 12. The FD 42_{A} of the pixel 2_{A} and the FD 42_{B} of the pixel 2_{B} are arranged at the same position, which is an upper right corner in the drawing, relative to the PD 40 in the same pixel region, and the transfer transistor 41_{A} or 41_{B} is formed at a position corresponding to one of four corners of the rectangular PD 40 at which the FD 42 is disposed.

Furthermore, in the first circuit layout example illustrated in A of FIG. 3, the pixel transistor regions 51₁ to 51₃ in which the shared pixel transistors are arranged are formed in the pixel region of the pixel 2_{B} including the PD 40_{B} that is smaller in photodiode size.

On the other hand, in the second circuit layout example in A of FIG. 4, the pixel transistor regions 51₁ and 51₂ are formed in the pixel region of the pixel 2_{B} including the PD 40_{B} that is smaller in photodiode size, but the pixel transistor region 51₃ is formed in the pixel region of the pixel 2_{A} including the PD 40_{A} that is larger in photodiode size. As described above, at least one of the pixel transistors may be disposed in the pixel region of the pixel 2_{A} including the PD 40_{A} that is larger in photodiode size.

Furthermore, the element isolation part 52 is divided into three element isolation parts 52₁ to 52₃, and each of the three element isolation parts 52₁ to 52₃ is disposed at a position corresponding to a position where a corresponding one of the pixel transistor regions 51₁ to 51₃ is formed. The element isolation part 52₁ isolates the PD 40_{B} from the pixel transistor region 51₁. The element isolation part 52₂ isolates the PD 40_{B} from the pixel transistor region 51₂. The element isolation part 52₃ isolates the PD 40_{A} from the pixel transistor region 51₃.

B of FIG. 4 is a plan view of an inside of a pixel array unit 3 in which a plurality of the pixel units 31 illustrated in A of FIG. 4 is regularly arranged. Note that, also in B of FIG. 4, reference numerals other than the pixel 2_{A} and the pixel 2_{B} are omitted.

According to the second circuit layout example of the pixel unit 31 in FIG. 4, the pixel 2_{A} including the PD 40_{A} that is larger in photodiode size and the pixel 2_{B} including the PD 40_{B} that is smaller in photodiode size than the PD 40_{A} are arranged adjacent to each other in the vertical direction. The pixel transistors shared by the pixel 2_{A} and the pixel 2_{B} are dispersedly arranged in the pixel transistor regions 51₁ and 51₂ of the pixel 2_{B} including the PD 40_{B} that is smaller in photodiode size and the pixel transistor region 51₃ of the pixel 2_{A} including the PD 40_{A} that is larger in photodiode size. It is therefore possible to increase the photodiode size of the PD 40_{A} of the pixel 2_{A} as much as possible and thus increase the sensitivity of the PD 40_{A}. In other words, it is possible to increase the SN ratio of the pixel signal of the pixel 2_{A}. Furthermore, an increase in the saturation signal amount of the PD 40_{A} allows an increase in dynamic range.

Furthermore, similarly to the first circuit layout example,
it is possible to prevent dark current by arranging the element isolation part 52 (52₁ to 52₃) in a concentrated manner and causing the element isolation part 52 to isolate the well contact part 53.

The second circuit layout example is also similar to the first circuit layout example in that the pixel 2_{A} and the pixel 2_{B} constituting the pixel unit 31 may be arranged adjacent to each other in the horizontal direction.

<Modification of Second Circuit Layout Example>

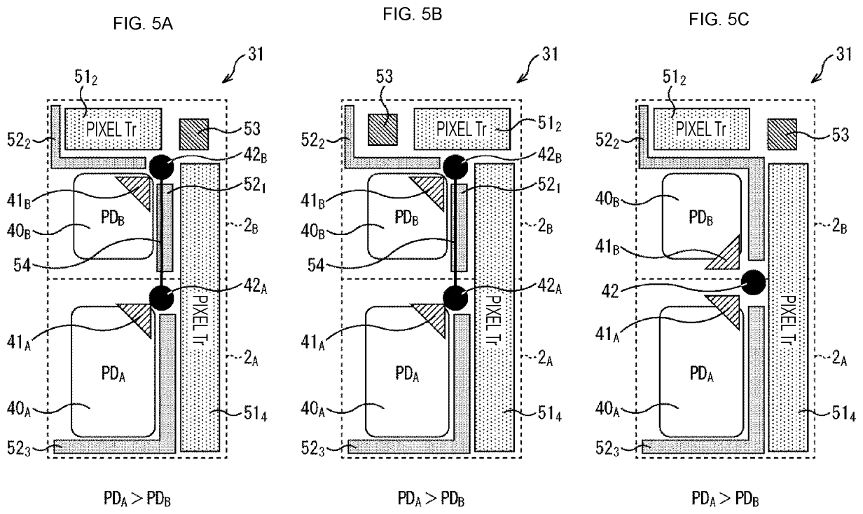

A to C of FIG. 5 are plan views of modifications of the second circuit layout example of the pixel unit 31.

A first modification illustrated in A of FIG. 5 is different in that the pixel transistor regions 51₁ and 51₃ formed separately into two in A of FIG. 4 are changed to one pixel transistor region 51₄, and the other points are common the second circuit layout example.

A second modification illustrated in B of FIG. 5 is different in that the positions of the well contact part 53 and the pixel transistor region 51₂ of the first modification in A of FIG. 5 are interchanged, and the other points are common to the first modification.

In the second modification, no well contact part 53 is provided between the pixel transistor regions 51₂ and 51₄, and the pixel transistor regions 51₂ and 51₄ are adjacent to each other accordingly, so that it is possible to reduce wirings connecting the sources or the drains of the pixel transistors each formed in a corresponding one of the pixel transistor regions 51₂ and 51₄. It is therefore possible to reduce coupling between wirings and thus reduce noise. The reduction in noise allows an increase in the SN ratio of the pixel signal. Furthermore, the reduction in the number of wirings allows a reduction in possibility of failure such as an open circuit or a short circuit in wiring and thus allows an increase in yield. The pixel transistor regions 51₂ and 51₄ may be connected to each other to form a continuous region.

A third modification illustrated in C of FIG. 5 is different from the first modification in A of FIG. 5 in the layout of the transfer transistors 41_{A} and 41_{B}, and the FD 42, and the other points are common to the first modification. In the first modification, the FD 42 (FD 42_{A}, FD 42_{B}) is provided in both the pixel 2_{A} and the pixel 2_{B}, and the two FDs 42 are electrically connected by the metal wiring 54. In the third modification, similarly to the first circuit layout example, one FD 42 is formed at a boundary of the pixel regions of the pixel 2_{A} and the pixel 2_{B}, and the transfer transistor 41_{A} and the transfer transistor 41_{B} are formed such that the one FD 42 is interposed between the transfer transistor 41_{A} and the transfer transistor 41_{B}.

The structure where one FD 42 is disposed at the pixel boundary, and the transfer transistors 41_{A} and 41_{B} are arranged such that the one FD 42 is interposed between the transfer transistors 41_{A} and 41_{B} eliminates the need of the metal wiring 54, which allows a reduction in coupling between wirings and thus allows a reduction in noise, as compared with the structure where the FD 42 is provided in both the pixel 2_{A} and the pixel 2_{B}, and the two FDs 42 are connected by the metal wiring 54. It is therefore possible to increase the SN ratio of the pixel signal.

Although not illustrated, a configuration where some of the first to third modifications are combined as desired is also possible. For example, a configuration where the layout of the transfer transistors 41_{A} and 41_{B}, and the FD 42 of the third modification in C of FIG. 5 and the layout of the pixel transistor region 51₂ and the well contact part 53 of the second modification in B of FIG. 5 are combined may be adopted.

It goes without saying that the layout of the pixel transistor regions 51₁ to 51₄ and the well contact part 53 described above is not limited to the above-described examples, and a layout where the positions are interchanged as desired in horizontal or vertical symmetry is also possible.

<5. Circuit Configuration Example of Pixel Unit Shared by Four Pixels>

Next, a case where at least a part of the readout circuit is shared by four pixels will be described.

Note that, also in the drawings of a configuration of sharing by four pixels described below, portions corresponding to the portions of the pixel unit shared by two pixels described above are denoted by the same reference numerals, and the description of the portions will be omitted as appropriate.

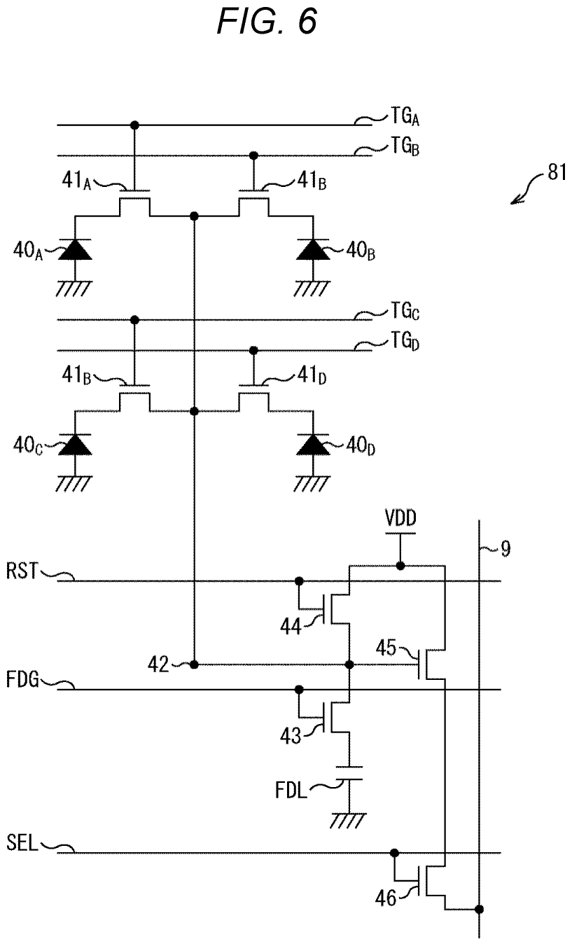

FIG. 6 illustrates a circuit configuration example of a pixel unit that is a unit to be shared in a case where the readout circuit is shared by four pixels.

A pixel unit 81 in FIG. 6 includes PDs 40_{A} to 40_{D}, transfer transistors 41_{A} to 41_{D}, an FD 42, a switching transistor 43, a reset transistor 44, an amplification transistor 45, a selection transistor 46, and an additional capacity FDL.

In the pixel unit 81 having the four pixels in FIG. 6 as a unit of sharing, each pixel includes only the PD 40 and the transfer transistor 41, and the FD 42, the switching transistor 43, the reset transistor 44, the amplification transistor 45, the selection transistor 46, and the additional capacity FDL are shared by the four pixels. When the four pixels constituting the pixel unit 81 are separated into pixels 2_{A}, 2_{B}, 2_{C}, and 2_{D}, the pixel 2_{A} includes the PD 40_{A} and the transfer transistor 41_{A}, and the pixel 2_{B} includes the PD 40_{B} and the transfer transistor 41_{B}. The pixel 2c includes the PD 40_{C} and the transfer transistor 41c, and the pixel 2_{D} includes the PD 40_{D} and the transfer transistor 41_{D}.

The other configuration and operation of the pixel unit 81 in FIG. 6 are similar to those in a case of the sharing by two pixels described with reference to FIG. 3.

In a case where the vertical driving circuit 4 turns on the transfer transistors 41_{A} to 41_{D} of the pixels 2_{A} to 2_{D} at different times to sequentially transfer the respective electric charges accumulated in the PDs 40_{A} to 40_{D} to the FD 42, the pixel signal is output, in units of pixels, to the column signal processing circuit 5.

On the other hand, in a case where the vertical driving circuit 4 simultaneously turns on the transfer transistors 41_{A} to 41_{D} of the pixel 2_{A} to 2_{D} to simultaneously transfer the respective electric charges accumulated in the PD 40_{A} to the PD 40D to the FD 42, the FD 42 functions as an addition unit, and an addition signal obtained by adding the pixel signals of the four pixels in the pixel unit 81 is output to the column signal processing circuit 5.

Therefore, the plurality of pixels 2 in the pixel unit 81 can output the pixel signal in units of one pixel or simultaneously output the pixel signals of the plurality of pixels 2 in the pixel unit 81 in accordance with a driving signal from the vertical driving circuit 4.

<6. First Circuit Layout Example of Pixel Unit Shared by Four Pixels>

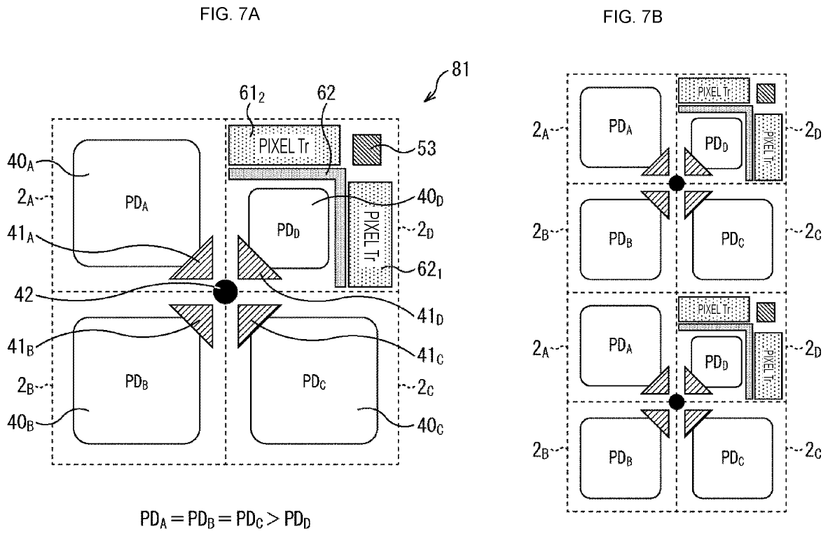

FIG. 7 is a plan view of a first circuit layout example of the pixel unit 81 shared by four pixels.

A of FIG. 7 is a plan view of one pixel unit 81 in the first circuit layout example.

The pixel unit 81 includes the pixels 2_{A} to 2_{D} arranged in four pixel regions of two rows and two columns. Specifically, the pixel 2_{A} is disposed in an upper-left pixel region of two rows and two columns, the pixel 2_{B} is disposed in a lower-left pixel region, the pixel 2_{C} is disposed in a lower-right pixel region, and the pixel 2_{D} is disposed in an upper-right pixel region. The respective pixel regions of the pixels 2 each indicated by a rectangular dashed line have the same size.

The FD 42 is formed at a center of the pixel unit 81 and at a boundary of the four pixel regions of two rows and two columns. The transfer transistors 41_{A} to 41_{D} of the pixels 2_{A} to 2_{D} are each formed near the FD 42 in a corresponding pixel region.

Regarding the photodiode size of each of the PDs 40 of the pixels 2_{A} to 2_{D}, the PDs 40_{A} to 40_{C} have the same size, and the PD 40_{B} is formed smaller in photodiode size than the PDs 40_{A} to 40_{C} (PD 40_{A}=PD 40_{B}=PD 40_{C}>PD 40_{B}). Pixel transistor regions 61₁ and 61₂ are formed in the pixel region of the pixel 2_{D} formed smaller in photodiode size than the other three pixels. The switching transistor 43, the reset transistor 44, the amplification transistor 45, the selection transistor 46, and the additional capacity FDL shared by the four pixels are dispersedly arranged in the pixel transistor regions 61₁ and 61₂.

An element isolation part 62 is formed between the pixel transistor regions 61₁ and 61₂, and the PD 40_{D}. The element isolation part 62 may include, for example, STI or a P-type impurity region. Arranging, in a concentrated manner, the pixel transistor regions 61₁ and 61₂ in one pixel region of the pixel 2_{D} also allows a reduction in area of the element isolation part 62, and it is therefore possible to prevent the occurrence of dark current due to a crystal defect caused by the formation of the element isolation part 62.

Furthermore, the well contact part 53 is disposed at a predetermined portion of the pixel region of the pixel 2_{D}. In A of FIG. 7, it is disposed at a position that is one of four corners of the rectangular pixel region of the pixel D and has an inside pixel region surrounded by the pixel transistor regions 61₁ and 61₂. As described above, a region around the well contact part 53 is used as the pixel transistor region 61, and the well contact part 53 and the PD 40_{D} are arranged so as not to be adjacent to each other, thereby allowing a reduction in influence of the dark current on the PD 40_{D}. Note that the well contact part 53 may be disposed, for example, at a boundary of the pixel regions of the pixels 2_{A} to 2_{D}, or may be disposed in the pixel regions of the pixels 2_{A} to 2_{C}.

B of FIG. 7 is a plan view of an inside of a pixel array unit 3 in which a plurality of the pixel units 81 illustrated in A of FIG. 7 is regularly arranged. Note that, in B of FIG. 7, reference numerals other than the pixels 2_{A} to 2_{D} are omitted.

According to the first circuit layout example of the pixel unit 81 in FIG. 7, the pixels 2_{A} to 2_{C} including the PD 40_{A} to the PD 40_{C} having the same photodiode size, and the pixel 2_{D} including the PD 40_{D} that is smaller in photodiode size than the PDs 40_{A} to 40_{C} are arranged in four pixel regions of two rows and two columns. All the pixel transistors shared by the pixels 2_{A} to 2_{D} are dispersedly arranged in the pixel transistor regions 61₁ and 61₂ of the pixel 2_{D} including the PD 40_{D} that is smaller in photodiode size. It is therefore possible to increase the photodiode size of the PD 40_{A} to the PD 40_{C} of the pixels 2_{A} to 2_{C} as much as possible and thus increase the sensitivity of the PD 40_{A} to the PD 40_{C}. In other words, it is possible to increase the SN ratio of the pixel signals of the pixels 2_{A} to 2_{C}. Furthermore, an increase in the saturation signal amount of the PD 40_{A} to the PD 40_{C} allows an increase in dynamic range.

<7. Second Circuit Layout Example of Pixel Unit Shared by Four Pixels>

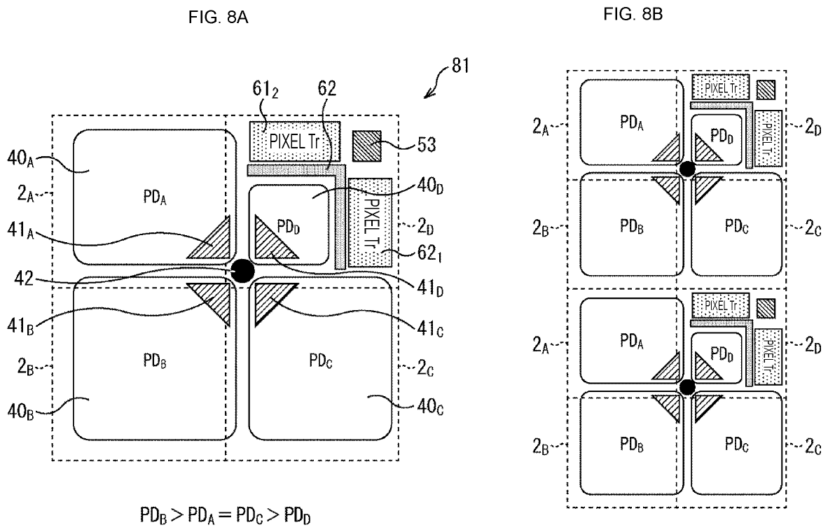

FIG. 8 is a plan view of a second circuit layout example of the pixel unit 81 shared by four pixels.

In FIG. 8, portions corresponding to the portions in FIG. 7 illustrated as the first circuit layout example are denoted by the same reference numerals, and description of the portions will be omitted as appropriate.

The second circuit layout example illustrated in A of FIG. 8 is different from the first circuit layout example illustrated in FIG. 7 in a magnitude relationship of the photodiode sizes of the PD 40_{A} to the PD 40_{D} of the pixels 2_{A} to 2_{D}. Specifically, in the first circuit layout example, the PD 40_{A} to the PD 40_{C} are formed in the same photodiode size, and the PD 40_{D} is formed smaller in photodiode size than the PD 40_{A} to the PD 40_{C} (PD 40_{A}=PD 40_{B}=PD 40_{C}>PD 40_{D}).

On the other hand, in the second circuit layout example, the PD 40_{B} is formed in the largest photodiode size, the PD 40_{A} and the PD 40_{C} are formed in the same photodiode size that is the second largest, and the PD 40_{D} is formed in the smallest photodiode size.

Furthermore, the PD 40_{B} having the largest photodiode size and the PD 40_{A} and PD 40_{C} having the second largest photodiode size each protrude outside a corresponding one of pixel regions obtained by equally dividing the four pixel regions of two rows and two columns in the vertical direction and the horizontal direction to an adjacent pixel region. The PD 40_{B} of the pixel 2_{B} is formed to protrude to the pixel regions of the pixels 2_{A}, 2_{C}, and 2_{D}. The PD 40_{A} of the pixel 2_{A} is formed to protrude to the pixel region of the pixel 2_{D}. The PD 40_{C} of the pixel 2_{C} is formed to protrude to the pixel region of the pixel 2_{D}.

The FD 42 and the transfer transistors 41_{A} to 41_{D} formed near the FD 42 are also arranged out of alignment with the center of the pixel unit 81 and protrude into the pixel region of the pixel 2_{D} in accordance with the shift in position of the PD 40_{A} to the PD 40_{C}.

A positional relationship between the pixel transistor regions 61₁ and 61₂, and the element isolation part 62 is similar to the positional relationship in the first circuit layout example illustrated in FIG. 7. The formation positions and sizes of the pixel transistor regions 61₁ and 61₂ and the element isolation part 62 may be changed.

B of FIG. 8 is a plan view of an inside of a pixel array unit 3 in which a plurality of the pixel units 81 illustrated in A of FIG. 8 is regularly arranged. Note that, in B of FIG. 8, reference numerals other than the pixels 2_{A} to 2_{D} are omitted.

As in the second circuit layout example illustrated in FIG. 8, each of the PD 40_{A} to the PD 40_{D} of the pixels 2_{A} to 2_{D} may be formed to protrude outside a corresponding one of the pixel regions equally divided. Actions and effects produced by the second circuit layout example of the pixel unit 81 in FIG. 8 are similar to the actions and effects produced by the first circuit layout example described above.

The first circuit layout example in FIG. 7 is an example having two different photodiode sizes, and the second circuit layout example in FIG. 8 is an example having three different photodiode sizes. Alternatively, the PDs 40_{A} to the PD 40_{D} of the pixels 2_{A} to 2_{D} may be made different in photodiode size from each other, and have four different photodiode sizes.

Furthermore, the above-described pixel unit 31 has a configuration where two pixels share the readout circuit, and the above-described pixel unit 81 has a configuration where four pixels share the readout circuit. A pixel unit in which a plurality of pixels that is neither two pixels nor four pixels shares the readout circuit may be employed. For example, a configuration where eight pixels share the readout circuit may be employed.

In the pixel unit 81 described above, of the four pixels of two rows and two columns, the pixel transistor regions 51₁ to 51₄ and the well contact part 53 are arranged in the upper-right pixel 2, but the pixel 2 in which such components are arranged is not limited to the upper-right pixel 2, and such components may be arranged in another pixel 2.

<8. Layout Example of Color Filter Layer>

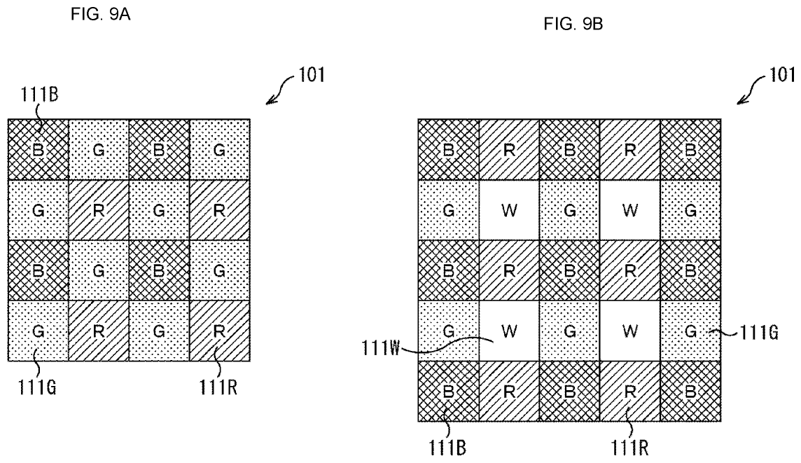

FIG. 9 is a plan view of a configuration example of a color filter layer formed on the light incident surface side (for example, the back surface) of the semiconductor substrate 12 in which the PD 40 is formed.

For example, as illustrated in A of FIG. 9, a color filter layer 101 may have a configuration where an R filter 111R that transmits a red (R) wavelength, a G filter 111G that transmits a green (G) wavelength, and a B filter 111B that transmits a blue (B) wavelength are arranged on a pixel-by-pixel basis in a predetermined arrangement such as a Bayer arrangement in pixel regions equally divided. The R filter 111R, the G filter 111G, and the B filter 111B are identical in plane size to each other and have a square plane shape.

Alternatively, as illustrated in B of FIG. 9, a configuration where four types of filters including a W filter 111W in addition to the R filter 111R, the G filter 111G, and the B filter 111B are regularly arranged in units of four pixels of two rows and two columns. The W filter 111W is a filter that transmits all wavelengths of red (R), green (G), blue (B), and infrared light (IR). The R filter 111R, the G filter 111G, the B filter 111B, and the W filter 111W are identical in plane size to each other and have a square plane shape. Instead of the W filter 111W, an IR filter that transmits only IR may be disposed.

Furthermore, the color filter layer 101 may adopt filters of complementary colors of cyan, magenta, and yellow instead of the R, G, and B filters.

On an upper side (light incident surface side) of the color filter layer 101, on-chip lenses (not illustrated) of the same size are further arranged on a pixel-by-pixel basis.

<9. Varied Size Layout Example of Color Filter Layer and On-Chip Lens>

In the above-described embodiment, an example where the PDs 40 formed in the pixel regions equally divided are varied in photodiode size in a manner that depends on pixels has been described, but the color filter layer and the on-chip lens formed on the light incident surface side of the semiconductor substrate 12 have the same size for each pixel.

Next, an example where the color filter layer and the on-chip lens are varied in size in a manner that depends on pixels will be described. Note that, in the following description, it is assumed that each pixel has the same photodiode size.

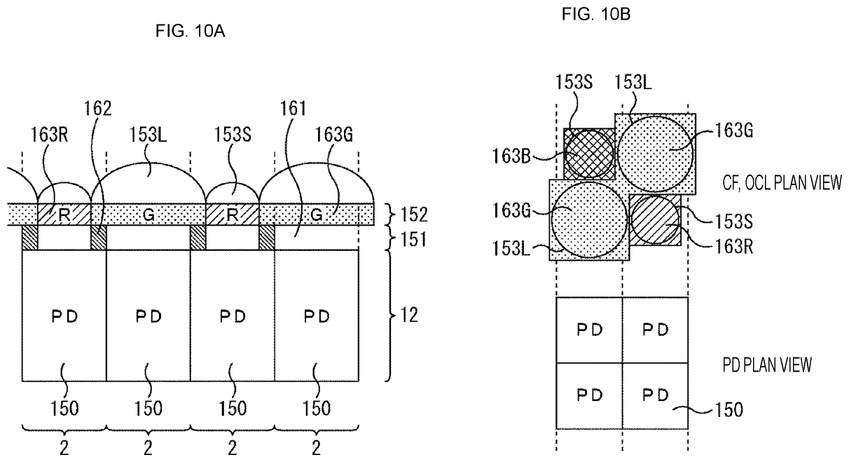

A of FIG. 10 is a cross-sectional view of a plurality of pixels arranged in a row in the vertical direction or the horizontal direction in the pixel array unit 3.

In the semiconductor substrate 12, PDs 150 having the same photodiode size are formed in pixel regions equally divided. A planarization layer 151, a color filter layer 152, and an on-chip lens 153 are formed on the light incident surface side of the semiconductor substrate 12 that is an upper side in the drawing.

The planarization layer 151 includes two planarization films 161 and 162 having different refractive indexes. For example, the planarization film 161 having a first refractive index is formed on an upper side of the PD 150, and the planarization film 162 having a second refractive index larger than the first refractive index is formed at a boundary between adjacent pixels. The planarization films 161 and 162 both include a material that transmits incident light, but have different refractive indexes so as to allow the planarization film 162 to reflect light traveling toward an adjacent pixel to prevent color mixing. Examples of the material of the planarization films 161 and 162 may include an oxide film (SiO2), a nitride film (SiN), an oxynitride film (SiON), silicon carbide (SiC), and the like.

In the color filter layer 152, an R filter 163R smaller in plane size than the pixel region, and a G filter 163G larger in plane size than the pixel region are alternately arranged. On the G filter 163G, an on-chip lens 153L is formed in a size that corresponds to the filter size of the G filter 163G and is larger in plane size than the pixel region. On the R filter 163R, an on-chip lens 153S is formed in a size that corresponds to the filter size of the R filter 163R and is smaller in plane size than the pixel region.

B of FIG. 10 illustrates a plan view of the PD 150 in A of FIG. 10 and a plan view of the color filter layer 152 and the on-chip lens 153.

The PD 150 of each pixel 2 is formed in each of the pixel regions equally divided, the PD 150 having the same size for all the pixels.

In the color filter layer 152, the R filter 163R, the G filter 163G, and a B filter 163B are arranged in the Bayer arrangement. In pixels in which the G filter 163G and the B filter 163B are arranged in a row, the B filter 163B is formed smaller in plane size than the pixel region in a manner similar to the R filter 163R, and the G filter 163G is formed larger in plane size than the pixel region. On the G filter 163G formed in the larger plane size, the on-chip lens 153L larger in plane size is formed, and on the R filter 163R and the B filter 163B formed in the smaller plane size, the on-chip lens 153S smaller plane size is formed.

As described above, the PD 150 of each pixel 2 is formed in the same size for all the pixels, and the color filter layer 152 and the on-chip lens 153 located on an upper portion of the PD 150, that is, on the light incident surface side, are varied in pixel size in a manner that depends on a color of light to be received, thereby allowing an increase in sensitivity of a desired pixel. Making the size of the PD 150 identical for all the pixels makes the saturation signal amount and a noise component such as dark current identical for all the pixels, so that it is possible to reduce variations in characteristics among the pixels.

For the solid-state imaging device 1 having such a structure, it is only required to change the sizes of the color filter layer 152 and the on-chip lens 153 formed on the semiconductor substrate 12, so that it is only required to change masks for the color filter layer 152 and the on-chip lens 153 as a change to the fabrication process, and it is also easy to control the characteristics. It is therefore possible to obtain desired characteristics at low cost.

Note that, in the example in FIG. 10, the R filter 162R, the G filter 162G, and the B filter 162B have a square plane shape having the same size in the vertical direction and the horizontal direction, but may have a rectangular plane shape having different lengths in the vertical direction and the horizontal direction.

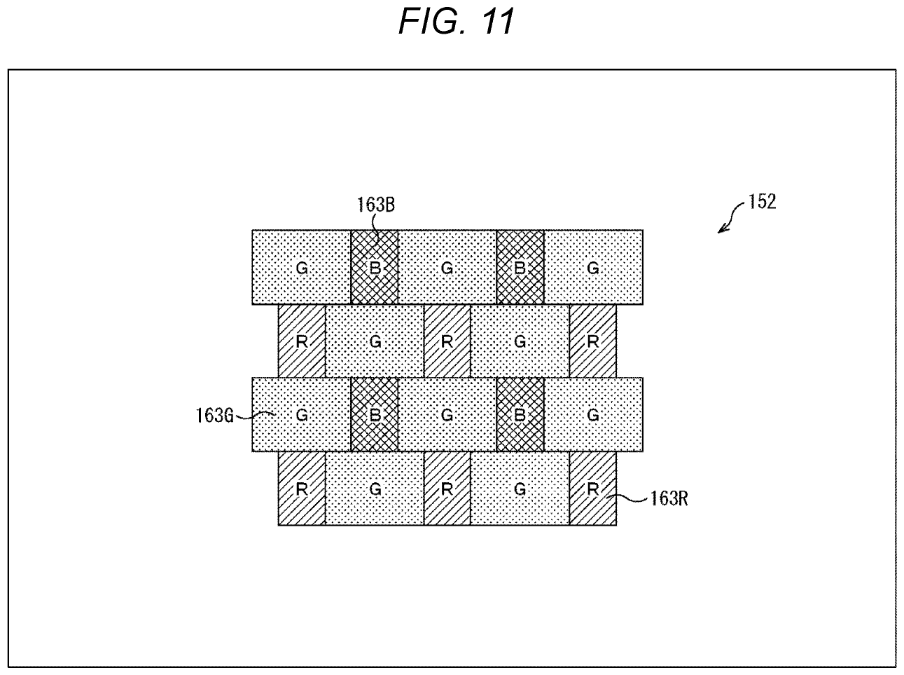

FIG. 11 is a plan view of an example in a case where the R filter 163R, the G filter 163G, and the B filter 163B have a rectangular plane shape.

In the color filter layer 152 in FIG. 11, the G filter 163G larger in plane size than the pixel region is formed in a horizontally long rectangular shape, and the R filter 163R and the B filter 163B smaller in plane size than the pixel region are formed in a vertically long rectangular shape. Note that the plane shape is not limited to a square shape or a rectangular shape, and may be a different shape such as a hexagonal shape or an octagonal shape, for example.

FIGS. 10 and 11 illustrate an example where, of the R filter 163R, the G filter 163G, and the B filter 163B, the G filter 163G is larger in plane size than the pixel region, and the R filter 163R and the B filter 163B are smaller in plane size than the pixel region, but it is possible to determine as desired which color filter is larger in plane size than the pixel region or smaller in plane size than the pixel region.

Furthermore, the arrangement of the R filter 163R, the G filter 163G, and the B filter 163B is not limited to the Bayer arrangement, and may be a different arrangement. The types of colors constituting the color filter layer 152 may also be a combination of complementary colors of cyan, magenta, and yellow rather than a combination of R, G, and B.

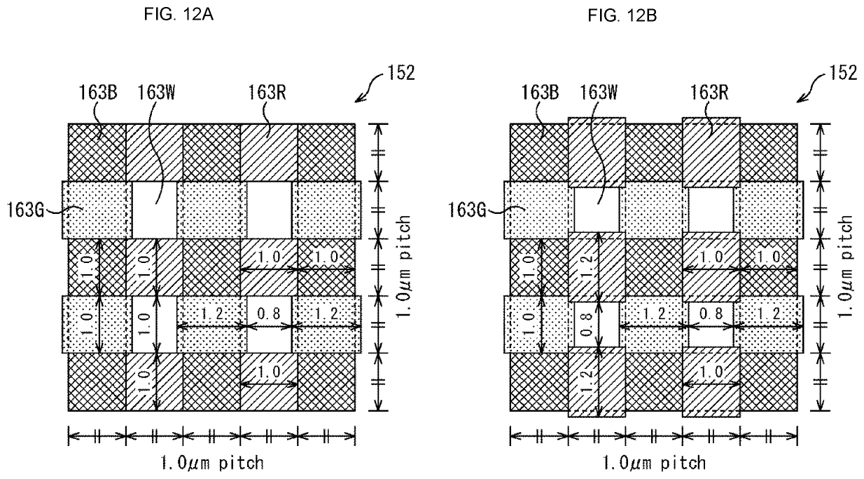

A and B of FIG. 12 illustrate layout examples of the color filter layer 152 including a W filter 163W in addition to the R filter 163R, the G filter 163G, and the B filter 163B.

In a first layout example including the W filter 163W illustrated in A of FIG. 12, the W filter 163W is formed in a (vertically long) rectangular shape that is smaller in plane size than the pixel region, and the G filter 163G is formed in a (horizontally long) rectangular shape that is larger in plane size than the pixel region. The R filter 163R and the B filter 163B are formed in a square shape that is identical in plane size to the pixel regions equally divided.

For example, in a case where the pixel size is 1 μm square, the W filter 163W is formed in a size of length*width=0.8 μm*1.0 μm, and the G filter 163G is formed in a size of length*width=1.0 μm*1.2 μm. The R filter 163R and the B filter 163B are each formed in a size of length*width=1.0 μm*1.0 μm.

In a second layout example including the W filter 163W illustrated in B of FIG. 12, the W filter 163W is formed in a square shape that is smaller in plane size than the pixel region, and the G filter 163G and the R filter 163R are formed in a rectangular shape that is larger in plane size than the pixel region. The B filter 163B is formed in a square shape that is identical in plane size to the pixel regions equally divided.

For example, in a case where the pixel size is 1 μm, the W filter 163W is formed in a size of length*width=0.8 μm*0.8 μm, and the G filter 163G is formed in a size of length*width=1.0 μm*1.2 μm. The R filter 163R is formed in a size of length*width=1.2 μm*1.0 μm, and the B filter 163B is formed in a size of length*width=1.0 μm*1.0 μm.

The pixel 2 including the W filter 163W is high in sensitivity because the W filter 163W does not absorb visible light, so that a phenomenon called blooming in which when the PD 150 becomes saturated, electric charges that cannot be accumulated overflow into an adjacent pixel tends to occur, which is likely to cause degradation in image quality. Therefore, a reduction in the plane size of the W filter 163W allows a reduction in sensitivity, so that it is possible to prevent quick saturation and suppress degradation in image quality such as blooming even under high light intensity.

Furthermore, an increase in the plane size of the G filter 163G allows an increase in sensitivity of the pixel 2 that receives light of a green wavelength and thus allows an increase in SN ratio. In particular, the effect is significant on a landscape image largely occupied with green and the like.

Instead of the W filter 163W in FIG. 12, an IR filter that transmits only infrared light (IR) may be used. As the types of colors constituting the color filter layer 152, a combination of complementary colors of cyan, magenta, and yellow may also be adopted instead of a combination of R, G, and B.

Each of the examples described with reference to FIGS. 10 to 12 is an example where filters such as R, G, B, and W filters having different transmission wavelengths are arranged in units of one pixel, but may be arranged in units of a plurality of pixels.

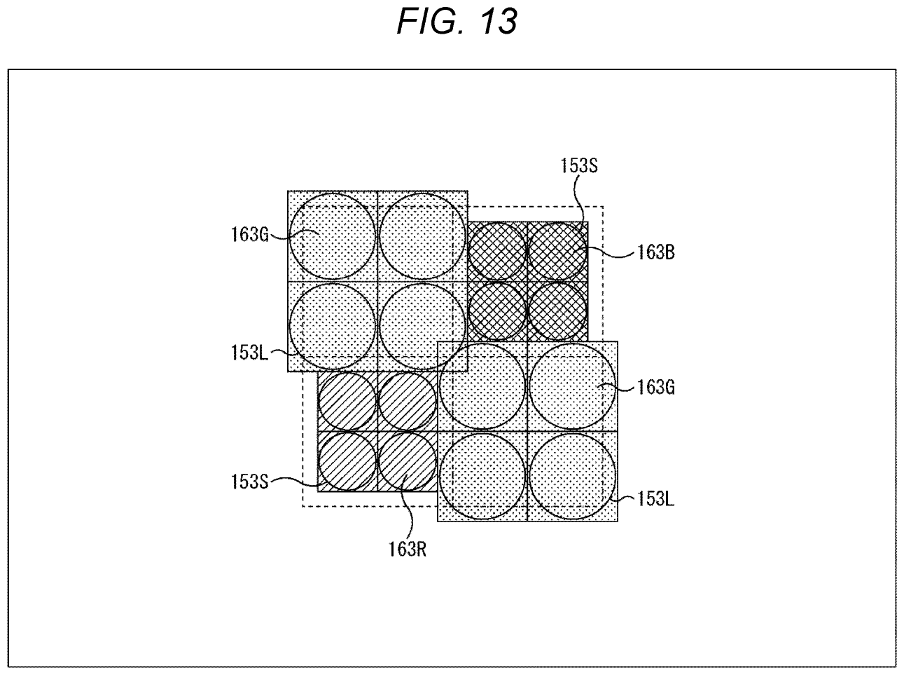

FIG. 13 is a plan view of a configuration where R, G, and B filters are arranged in the Bayer arrangement in units of four pixels of two rows and two columns, and the filter size and the on-chip lens size are changed.

FIG. 13 corresponds to a case where the color filter layer 152 and the on-chip lens 153 illustrated in FIG. 10 are arranged in units of four pixels of two rows and two columns.

<10. Combination of PDs Having Different Sizes>

A pixel structure that is a combination of a structure where the color filter layer 152 and the on-chip lens 153 described with reference to FIGS. 10 to 13 are varied in plane size in a manner that depends on the pixels 2 and a structure where the photodiode size described with reference to FIGS. 2 to 8 is varied in a manner that depends on the pixels 2 may be adopted. For example, a pixel structure where the G filter 162G larger in plane size than the pixel region is disposed in the pixel 2_{A} including the PD 40_{A} larger in photodiode size, and the B filter 162B or the R filter 162R smaller in plane size than the pixel region is disposed in the pixel 2_{B} including the PD 40_{B} smaller in photodiode size may be employed. The same applies to the on-chip lenses 153S and 153L.

<11. Application Example to Electronic Apparatus>

The present technology is not limited to application to a solid-state imaging device. That is, the present technology can be applied to all electronic apparatuses that use a solid-state imaging device for an image capture unit (photoelectric converting unit), such as an imaging device such as a digital still camera or video camera, a portable terminal device having an imaging function, or a copying machine using a solid-state imaging device in an image reading unit. The solid-state imaging device may be formed as a single chip, or may be formed as a module having an imaging function in which an imaging unit and a signal processing unit or an optical system are packaged together.

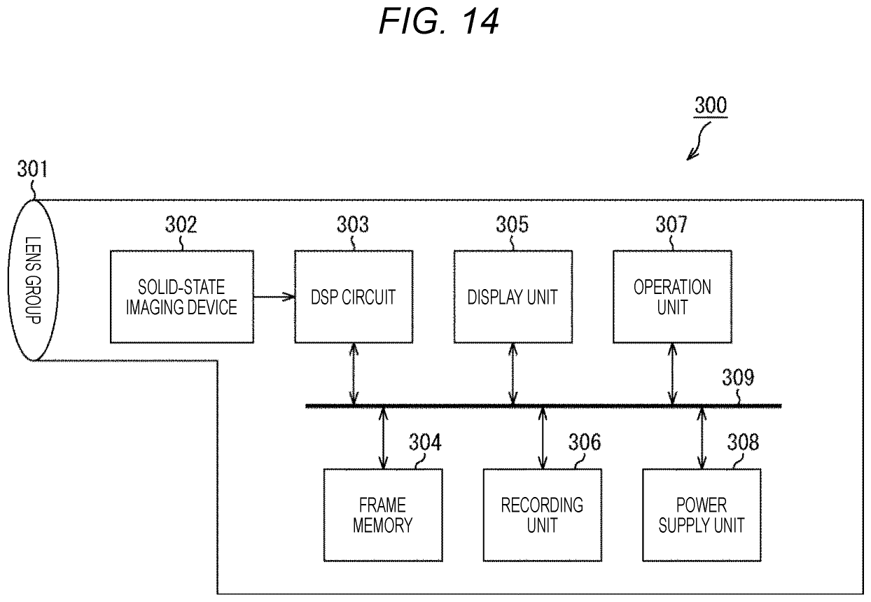

FIG. 14 is a block diagram illustrating a configuration example of an imaging device as an electronic apparatus to which the present technology is applied.

An imaging device 300 in FIG. 14 is provided with an optical unit 301 including a lens group and the like, a solid-state imaging device (imaging device) 302 to which the configuration of the solid-state imaging device 1 in FIG. 1 is adopted, and a digital signal processor (DSP) circuit 303 being a camera signal processing circuit. Furthermore, the imaging device 300 includes a frame memory 304, a display unit 305, a recording unit 306, an operation unit 307, and a power supply unit 308. The DSP circuit 303, the frame memory 304, the display unit 305, the recording unit 306, the operation unit 307, and the power supply unit 308 are connected to one another through a bus line 309.

The optical unit 301 captures incident light (image light) from a subject and forms an image on an imaging surface of the solid-state imaging device 302. The solid-state imaging device 302 converts the light amount of the incident light imaged on the imaging surface by the optical unit 301 into an electrical signal in units of pixels and outputs the electrical signal as a pixel signal. As the solid-state imaging device 302, the solid-state imaging device 1 in FIG. 1, that is, a solid-state imaging device in which the pixels 2 having different photodiode sizes are arranged in a two-dimensional array, a solid-state imaging device in which the color filter layer 152 and the on-chip lens 153 are formed in different sizes in a manner that depends on the pixels 2, or the like may be used.

For example, the display unit 305 includes a thin display such as a liquid crystal display (LCD) or an organic electro luminescence (EL) display, and displays a moving image or a still image captured by the solid-state imaging device 302. The recording unit 306 records a moving image or a still image captured by the solid-state imaging device 302 on a recording medium such as a hard disk or a semiconductor memory.

The operation unit 307 issues an operation command regarding various functions of the imaging device 300 under operation by a user. The power supply unit 308 appropriately supplies various power to be operation power supply for the DSP circuit 303, the frame memory 304, the display unit 305, the recording unit 306, and the operation unit 307, to these supply targets.

As described above, the use of the solid-state imaging device 1 to which the above-described embodiment is applied as the solid-state imaging device 302 allows an increase in sensitivity of a specific pixel and allows an increase in SN ratio. Therefore, even in the imaging device 300 such as a video camera, a digital still camera, or a camera module for a mobile device such as a mobile phone or the like, the image quality of the captured image can be improved.

<Usage Example of Image Sensor>

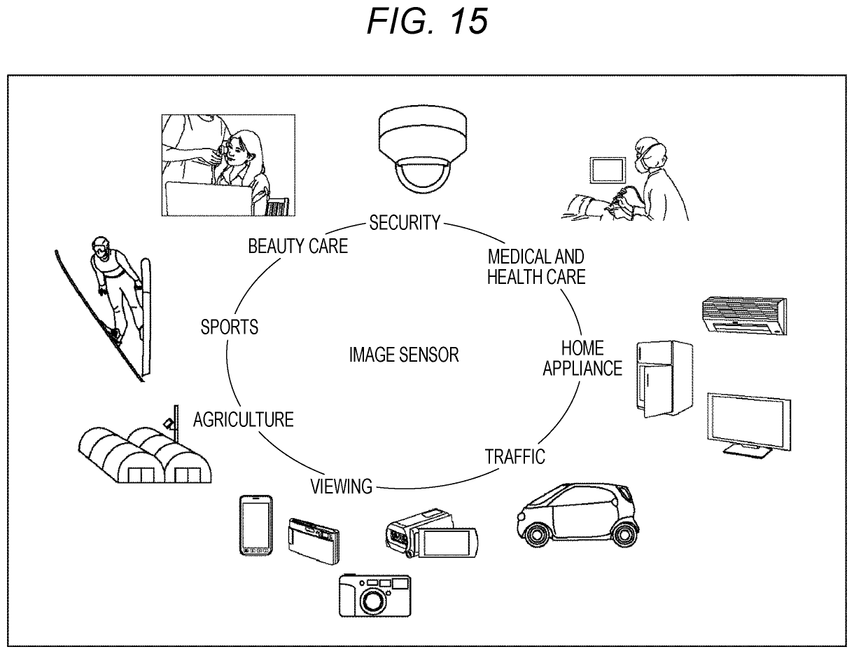

FIG. 15 is a diagram illustrating a usage example of an image sensor using the above-described solid-state imaging device 1.

The image sensor using the above-described solid-state imaging device 1 can be used, for example, in various cases of sensing light such as visible light, infrared light, ultraviolet light, X-rays, and the like as follows.
A device which takes an image to be used for viewing such as a digital camera and portable equipment with a camera function
A device for traffic purpose such as a vehicle-mounted sensor that takes images of the front, rear, surroundings, interior and the like of an automobile, a monitoring camera that monitors traveling vehicles and roads, and a ranging sensor that measures a distance between vehicles and the like for safe driving such as automatic stop, recognition of a driver's condition and the like
A device for home appliance such as a television, a refrigerator, and an air conditioner that images a user's gesture and performs device operation according to the gesture
A device for medical and health care use such as an endoscope and a device that performs angiography by receiving infrared light
A device for security use such as a security monitoring camera and an individual authentication camera
A device for beauty care use such as a skin measuring device that images skin and a microscope that images scalp
A device for sporting use such as an action camera and a wearable camera for sporting use and the like
A device for agricultural use such as a camera for monitoring land and crop states

The present technology is applicable to any light detection device including not only the above-described solid-state imaging device as an image sensor but also a ranging sensor also called a time of flight (ToF) sensor that measures a distance, and the like. The ranging sensor is a sensor that emits irradiation light toward an object, detects reflected light that is the irradiation light reflected off a surface of the object, and calculates a distance to the object on the basis of a flight time from the emission of the irradiation light to the reception of the reflected light. As a light receiving pixel structure of the ranging sensor, the above-described structure of the pixel 2 may be adopted.

Note that the effects described herein are merely examples and are not restrictive, and effects other than those described herein may be obtained.

Note that the present technology may also take the following configuration.
(1)

A light detection device including
a pixel array unit in which a plurality of pixels is regularly arranged, the plurality of pixels including
a first pixel and a second pixel, the first pixel including at least a photodiode and one or more pixel transistors, the second pixel including at least a photodiode larger in size than the photodiode of the first pixel, in which
the pixel transistor in the first pixel is shared by the first pixel and the second pixel.
(2)

The light detection device according to the above (1), in which
the second pixel further includes at least one pixel transistor, and
the pixel transistor in the second pixel is also shared by the first pixel and the second pixel.
(3)

The light detection device according to the above (1) or (2), further including
an element isolation part between the pixel transistor and the photodiode of the first pixel.
(4)

The light detection device according to any one of the above (1) to (3), in which
the first pixel further includes a well contact part where a predetermined voltage is applied to a well.
(5)

The light detection device according to any one of the above (1) to (4), in which
the pixel transistor in the first pixel is shared by the first pixel and a plurality of the second pixels.
(6)

The light detection device according to the above (5), in which
the first pixel and three of the second pixels are arranged in four pixel regions of two rows and two columns.

(7)

The light detection device according to the above (1), in which
the pixel array unit further includes a third pixel including at least a photodiode larger in size than the photodiode of the second pixel, and
the pixel transistor in the first pixel is shared by the first pixel, two of the second pixels, and the third pixel.
(8)

The light detection device according to the above (7), in which
the first pixel, the two second pixels, and the third pixel are arranged in four pixel regions of two rows and two columns, and
each photodiode of the two second pixels and the third pixel is formed to protrude outside a pixel region obtained by equally dividing the four pixel regions of two rows and two columns in a vertical direction and a horizontal direction to an adjacent pixel region.
(9)

The light detection device according to any one of (1) to (8), in which
the pixel array unit further includes a color filter layer and an on-chip lens on an upper side of the photodiode of each of the pixels, the color filter layer including an R filter, a G filter, or a B filter.
(10)

The light detection device according to the above (9), in which
the R filter, the G filter, or the B filter and the on-chip lens are identical in plane size to each other.
(11)

The light detection device according to the above (9), in which
the plane size of the R filter or the B filter and the on-chip lens
is smaller than the plane size of the G filter and the on-chip lens.
(12)

The light detection device according to the above (11), in which
the R filter, the G filter, or the B filter has a square plane shape.
(13)

The light detection device according to the above (11), in which
the R filter, the G filter, or the B filter has a rectangular plane shape.
(14)

The light detection device according to any one of the above (9) to (11), in which
the color filter layer further includes a W filter or an IR filter.
(15)

The light detection device according to the above (14), in which
the W filter or the IR filter has a square plane shape.
(16)

The light detection device according to the above (14) or (15), in which
the R filter, the G filter, and the B filter each have a square plane shape.
(17)

The light detection device according to the above (14), in which
the W filter or the IR filter has a rectangular plane shape.
(18)

The light detection device according to the above (1) to (17), in which
the pixel array unit includes a color filter layer and an on-chip lens on an upper side of the photodiode of each of the pixels, the color filter layer including an R filter, a G filter, or a B filter, and
filters identical in color to the R filter, the G filter, or the B filter are arranged in units of a plurality of pixels.
(19)

An electronic apparatus including
a light detection device including
a pixel array unit in which a plurality of pixels is regularly arranged, the plurality of pixels including
a first pixel and a second pixel, the first pixel including at least a photodiode and one or more pixel transistors, the second pixel including at least a photodiode larger in size than the photodiode of the first pixel, in which
the pixel transistor in the first pixel is shared by the first pixel and the second pixel.
(20)

A light detection device including
a pixel array unit in which a plurality of pixels is regularly arranged, the plurality of pixels including photodiodes of the same size, in which
the pixel array unit includes color filter layers and on-chip lenses of different sizes on upper sides of the photodiodes.

### REFERENCE SIGNS LIST

1 Solid-state imaging device
2, 2A to 2D Pixel
3 Pixel array unit
12 Semiconductor substrate
31 Pixel unit
40, 40A to 40D PD
41, 41A to 41D Transfer transistor
42 FD
43 Switching transistor
FDL Additional capacity
44 Reset transistor
45 Amplification transistor
46 Selection transistor
51, 51₁ to 51₄ Pixel transistor region
52, 52₁ to 52₃ Element isolation part
53 Well contact part
54 Metal wiring
61, 61₁, 61₂ Pixel transistor region
62 Element isolation part
81 Pixel unit
101 Color filter layer
111B B filter
111G G filter
111R R filter
111W W filter
126W W filter
150 PD
151 Planarization layer
152 Color filter layer
153, 153L, 153S On-chip lens
161, 162 Planarization film
163B B filter
163G G filter
163R R filter
300 Imaging device
302 Solid-state imaging device

1. A light detection device comprising
a pixel array unit in which a plurality of pixels is regularly arranged, the plurality of pixels including
a first pixel and a second pixel, the first pixel including at least a photodiode and one or more pixel transistors, the second pixel including at least a photodiode larger in size than the photodiode of the first pixel, wherein
the pixel transistor in the first pixel is shared by the first pixel and the second pixel.

2. The light detection device according to claim 1, wherein
the second pixel further includes at least one pixel transistor, and
the pixel transistor in the second pixel is also shared by the first pixel and the second pixel.

3. The light detection device according to claim 1, further comprising
an element isolation part between the pixel transistor and the photodiode of the first pixel.

4. The light detection device according to claim 1, wherein
the first pixel further includes a well contact part where a predetermined voltage is applied to a well.

5. The light detection device according to claim 1, wherein
the pixel transistor in the first pixel is shared by the first pixel and a plurality of the second pixels.

6. The light detection device according to claim 5, wherein
the first pixel and three of the second pixels are arranged in four pixel regions of two rows and two columns.

7. The light detection device according to claim 1, wherein
the pixel array unit further includes a third pixel including at least a photodiode larger in size than the photodiode of the second pixel, and
the pixel transistor in the first pixel is shared by the first pixel, two of the second pixels, and the third pixel.

8. The light detection device according to claim 7, wherein
the first pixel, the two second pixels, and the third pixel are arranged in four pixel regions of two rows and two columns, and
each photodiode of the two second pixels and the third pixel is formed to protrude outside a pixel region obtained by equally dividing the four pixel regions of two rows and two columns in a vertical direction and a horizontal direction to an adjacent pixel region.

9. The light detection device according to claim 1, wherein
the pixel array unit further includes a color filter layer and an on-chip lens on an upper side of the photodiode of each of the pixels, the color filter layer including an R filter, a G filter, or a B filter.

10. The light detection device according to claim 9, wherein
the R filter, the G filter, or the B filter and the on-chip lens are identical in plane size to each other.

11. The light detection device according to claim 9, wherein
the plane size of the R filter or the B filter and the on-chip lens
is smaller than the plane size of the G filter and the on-chip lens.

12. The light detection device according to claim 11, wherein
the R filter, the G filter, or the B filter has a square plane shape.

13. The light detection device according to claim 11, wherein
the R filter, the G filter, or the B filter has a rectangular plane shape.

14. The light detection device according to claim 9, wherein
the color filter layer further includes a W filter or an IR filter.

15. The light detection device according to claim 14, wherein
the W filter or the IR filter has a square plane shape.

16. The light detection device according to claim 14, wherein
the R filter, the G filter, and the B filter each have a square plane shape.

17. The light detection device according to claim 14, wherein
the W filter or the IR filter has a rectangular plane shape.

18. The light detection device according to claim 1, wherein
the pixel array unit includes a color filter layer and an on-chip lens on an upper side of the photodiode of each of the pixels, the color filter layer including an R filter, a G filter, or a B filter, and
filters identical in color to the R filter, the G filter, or the B filter are arranged in units of a plurality of pixels.

19. An electronic apparatus comprising
a light detection device including
a pixel array unit in which a plurality of pixels is regularly arranged, the plurality of pixels including
a first pixel and a second pixel, the first pixel including at least a photodiode and one or more pixel transistors, the second pixel including at least a photodiode larger in size than the photodiode of the first pixel, wherein
the pixel transistor in the first pixel is shared by the first pixel and the second pixel.

20. A light detection device comprising
a pixel array unit in which a plurality of pixels is regularly arranged, the plurality of pixels including photodiodes of a same size, wherein
the pixel array unit includes color filter layers and on-chip lenses of different sizes on upper sides of the photodiodes.
